(19) United States
(12) Patent Application Publication
(10) Pub. No.: US 2024/0422996 A1
(43) Pub. Date: Dec. 19, 2024

(54) NONVOLATILE MEMORY DEVICES AND METHODS OF FABRICATING THE SAME

(71) Applicant: Samsung Electronics Co., Ltd., Suwon-si (KR)

(72) Inventors: Bon Jae Koo, Suwon-si (KR); Seul Ji Song, Suwon-si (KR); Hwa Yeong Lee, Suwon-si (KR)

(21) Appl. No.: 18/413,281

(22) Filed: Jan. 16, 2024

(30) Foreign Application Priority Data
Jun. 16, 2023 (KR) 10-2023-0077331

(51) Int. Cl. H10B 99/00

(52) U.S. Cl. CPC H10B 99/10

(57) ABSTRACT

A nonvolatile memory device may include a substrate, a plurality of gate electrodes stacked on the substrate, a first conductive pillar that extends in a first direction and intersects the gate electrodes, a second conductive pillar that extends in the first direction and intersects the gate electrodes, the second conductive pillar being spaced apart from the first conductive pillar, an information storage film between the first conductive pillar and each of the gate electrodes and between the second conductive pillar and each of the gate electrodes, the information storage film including chalcogenide, a conductive layer spaced apart from the gate electrodes in the first direction, a first charge dissipation layer between the first conductive pillar and the conductive layer, and a second charge dissipation layer between the second conductive pillar and the conductive layer, the second charge dissipation layer being spaced apart from the first charge dissipation layer.

### CROSS-REFERENCE TO RELATED APPLICATION

This application claims priority from Korean Patent Application No. 10-2023-0077331 filed on Jun. 16, 2023, in the Korean Intellectual Property Office, and all the benefits accruing therefrom under 35 U.S.C. 119, the contents of which in its entirety are herein incorporated by reference.

### BACKGROUND

The present disclosure relates to nonvolatile memory devices and methods of fabricating the same, and more particularly, to chalcogenide-based nonvolatile memory devices and methods of fabricating the same.

Semiconductor memory devices may be classified into volatile memory devices, such as, for example, a static random-access memory (SRAM), a dynamic random-access memory (DRAM), or a synchronous DRAM (SDRAM), which lose the stored data when the power supply is interrupted, and non-volatile memory devices, such as, for example, a read-only memory (ROM), a programmable ROM (PROM), an electrically programmable ROM (EPROM), an electrically erasable and programmable ROM (EEPROM), a flash memory device, a phase-change random-access memory (PRAM), a magnetic random-access memory (MRAM), a resistive random-access memory (RRAM), or a ferroelectric random-access memory (FRAM), which retain the stored data even when the power supply is interrupted.

Recently, research utilizing chalcogenide-based materials with a threshold voltage, aimed at improving the performance of semiconductor memory devices, has been conducted.

### SUMMARY

Aspects of the present disclosure provide nonvolatile memory devices with improved integration, performance, and reliability.

Aspects of the present disclosure also provide methods of fabricating nonvolatile memory devices with improved integration, performance, and reliability.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to aspects of the present disclosure, a nonvolatile memory device may include a substrate, a plurality of gate electrodes stacked on the substrate, a first conductive pillar that extends in a first direction perpendicular to a top surface of the substrate and intersects the plurality of gate electrodes, a second conductive pillar that extends in the first direction and intersects the plurality of gate electrodes, the second conductive pillar being spaced apart from the first conductive pillar, an information storage film between the first conductive pillar and each of the plurality of gate electrodes and between the second conductive pillar and each of the plurality of gate electrodes, the information storage film including chalcogenide, a conductive layer spaced apart from the plurality of gate electrodes in the first direction, a first charge dissipation layer between the first conductive pillar and the conductive layer, and a second charge dissipation layer between the second conductive pillar and the conductive layer, the second charge dissipation layer being spaced apart from the first charge dissipation layer.

According to aspects of the present disclosure, a nonvolatile memory device may include a substrate, a mold stack including mold insulating films and gate electrodes alternately stacked on the substrate, a plurality of conductive pillars spaced apart from one another, each of the plurality of conductive pillars extending into the mold stack in a first direction perpendicular to a top surface of the substrate, a plurality of information storage films between the mold stack and each of the plurality of conductive pillars, each of the plurality of information storage films including chalcogenide, a conductive layer on the mold stack, a plurality of charge dissipation layers between the conductive layer and each of the plurality of conductive pillars, the plurality of charge dissipation layers being spaced apart from one another, a first conductive line that extends on the substrate in a second direction intersecting the first direction, a second conductive line that extends in a third direction between the first conductive line and the mold stack, the third direction intersecting the first and second directions, a selection channel pattern that extends into the second conductive line in the first direction, the selection channel pattern configured to electrically connect the first conductive line to one of the plurality of conductive pillars, and a selection gate dielectric film between the second conductive line and the selection channel pattern.

According to aspects of the present disclosure, a nonvolatile memory device may include a substrate, a mold stack including mold insulating films and gate electrodes alternately stacked on the substrate, a plurality of conductive pillars spaced apart from one another, each of the plurality of conductive pillars extending into the mold stack in a first direction perpendicular to a top surface of the substrate, a plurality of information storage films between the mold stack and each of the plurality of conductive pillars, the information storage films including chalcogenide, a charge dissipation layer that extends along a top surface of the mold stack and top surfaces of the plurality of conductive pillars, and a conductive layer on a top surface of the charge dissipation layer. Each of the plurality of conductive pillars may protrude beyond the top surface of the mold stack.

It should be noted that the aspects of the present disclosure are not limited to those described above, and other aspects of the present disclosure will be apparent from the following description.

### BRIEF DESCRIPTION OF THE DRAWINGS

The above and other aspects and features of the present disclosure will become more apparent by describing in detail example embodiments thereof with reference to the attached drawings, in which:

FIG. 1 is a block diagram of a nonvolatile memory device according to some embodiments of the present disclosure.

FIG. 2 is an exploded perspective view of a nonvolatile memory device according to some embodiments of the present disclosure.

FIGS. 3 and 4 are enlarged cross-sectional views of a region R1 of FIG. 2.

FIG. 5 is an exploded perspective view of a nonvolatile memory device according to some embodiments of the present disclosure.

FIG. 6 is an enlarged cross-sectional view of a region R2 of FIG. 5.

FIG. 7 is an exploded perspective view of a nonvolatile memory device according to some embodiments of the present disclosure.

FIG. 8 is an enlarged cross-sectional view of a region R3 of FIG. 7.

FIG. 9 is an exploded perspective view of a nonvolatile memory device according to some embodiments of the present disclosure.

FIG. 10 is an enlarged cross-sectional view of a region R4 of FIG. 9.

FIG. 11 is an exploded perspective view of a nonvolatile memory device according to some embodiments of the present disclosure.

FIG. 12 is an enlarged cross-sectional view of a region R5 of FIG. 11.

FIG. 13 is an exploded perspective view of a nonvolatile memory device according to some embodiments of the present disclosure.

FIG. 14 is an enlarged cross-sectional view of a region R6 of FIG. 13.

FIGS. 15 through 22 are perspective views illustrating intermediate steps of a method of fabricating a nonvolatile memory device according to some embodiments of the present disclosure.

FIGS. 23 through 28 are perspective views illustrating intermediate steps of a method of fabricating a nonvolatile memory device according to some embodiments of the present disclosure.

FIGS. 29 and 30 are perspective views illustrating intermediate steps of a method of fabricating a nonvolatile memory device according to some embodiments of the present disclosure.

FIGS. 31 through 33 are perspective views illustrating intermediate steps of a method of fabricating a nonvolatile memory device according to some embodiments of the present disclosure.

FIGS. 34 and 35 are perspective views illustrating intermediate steps of a method of fabricating a nonvolatile memory device according to some embodiments of the present disclosure.

### DETAILED DESCRIPTION

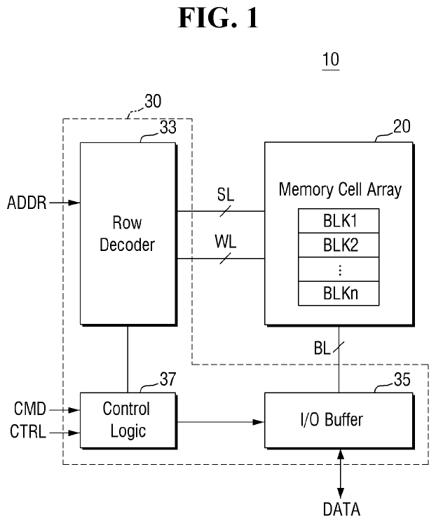

Nonvolatile memory devices according to some embodiments of the present disclosure will hereinafter be described with reference to FIGS. 1 through 14.

FIG. 1 is a block diagram of a nonvolatile memory device according to some embodiments of the present disclosure.

Referring to FIG. 1, a nonvolatile memory device 10 may include a memory cell array 20 and a peripheral circuit 30.

The memory cell array 20 may include a plurality of memory cell blocks BLK1 through BLKn. Each of the memory cell blocks BLK1 through BLKn may include a plurality of memory cells. The memory cell array 20 may be connected to the peripheral circuit 30 through bitlines BL, wordlines WL, and selection lines SL. Specifically, the memory cell blocks BLK1 through BLKn may be connected to a row decoder 33 through the wordlines WL and the selection lines SL. The memory cell blocks BLK1 through BLKn may be connected to an input/output buffer (I/O buffer, or latch) 35 through the bitlines BL.

The peripheral circuit 30 may receive an address ADDR, commands CMD, and control signals CTRL from outside the nonvolatile memory device 10 (e.g., external to the nonvolatile memory device 10) and may exchange data “DATA” with an external device outside the nonvolatile memory device 10. The peripheral circuit 30 may include the row decoder 33, the I/O buffer 35, and a control logic 37. Although not specifically depicted, the peripheral circuit 30 may further include various sub-circuits such as an input/output circuit, a voltage generation circuit for generating voltages necessary for the operation of the nonvolatile memory device 10, and an error correction circuit for correcting error in data “DATA” read from the memory cell array 20.

The control logic 37 may be connected to the row decoder 33, the I/O buffer 35, the input/output circuit, and the voltage generation circuit. The control logic 37 may control the general operation of the nonvolatile memory device 10. The control logic 37 may generate various inner control signals for use in the nonvolatile memory device 10 in response to the control signals CTRL. For example, the control logic 37 may control the voltages provided to the wordlines WL and the bitlines BL during a memory operation such as a program operation or an erase operation.

The row decoder 33 may select at least one of the memory cell blocks BLK1 through BLKn in response to the address ADDR and may select at least one of the wordlines WL and at least one of the selection lines SL of the selected memory cell block(s). Also, the row decoder 33 may transmit voltages for performing memory operations to the wordline(s) WL of the selected memory cell block(s).

The I/O buffer 35 may be connected to the memory cell array 20 via the bitlines BL. The I/O buffer 35 may function as a write driver or a sense amplifier. For example, during a program operation, the I/O buffer 35 may function as a write driver and may apply a voltage corresponding to data “DATA” to be stored in the memory cell array 20 to the bitlines BL. During a read operation, the I/O buffer 35 may function as a sense amplifier and may sense data “DATA” stored in the memory cell array 20.

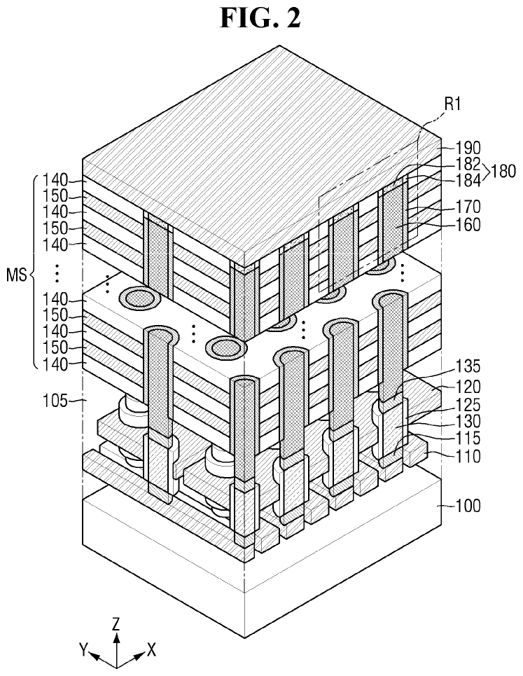

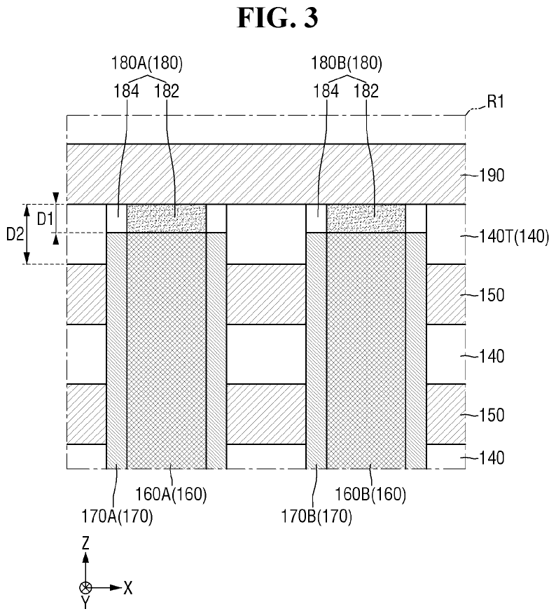

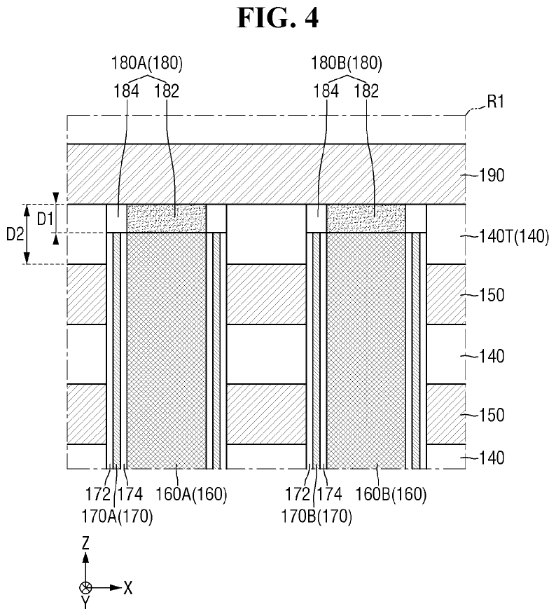

FIG. 2 is an exploded perspective view of a nonvolatile memory device according to some embodiments of the present disclosure. FIGS. 3 and 4 are enlarged cross-sectional views of a region R1 of FIG. 2.

Referring to FIGS. 2 and 3, the nonvolatile memory device according to some embodiments of the present disclosure may include a substrate 100, first conductive lines 110, second conductive lines 120, selection gate dielectric films 125, selection channel patterns 130, a mold stack MS, conductive pillars 160, information storage films 170, charge dissipation layers 180, and a conductive layer 190.

The substrate 100 may be a bulk silicon (Si) substrate or a silicon-on-insulator (SOI) substrate. The substrate 100 may be a Si substrate or may include a material other than Si, such as, for example, silicon germanium, gallium arsenide, silicon germanium-on-insulator (SGOI), indium antimonide, a lead tellurium compound, indium arsenide, indium phosphide, gallium arsenide, or gallium antimonide. As another example, the substrate 100 may be a base substrate with an epitaxial layer formed thereon or may be a ceramic substrate, a quartz substrate, or a glass substrate for a display.

The first conductive lines 110 may be formed on the substrate 100. The first conductive lines 110 may be two-dimensionally arranged on a plane (e.g., an XY plane) that is parallel to the top surface of the substrate 100. For example, the first conductive lines 110 may extend in a first direction Y and may be arranged along a second direction X to be spaced apart from one another. For example, the first conductive lines 110 may extend longitudinally in the first direction Y. The first conductive lines 110 may be provided as bitlines (e.g., the bitlines BL of FIG. 1). As used herein, the term “longitudinally” indicates a longest dimension.

The second conductive lines 120 may be formed on the first conductive lines 110. The second conductive lines 120 may be interposed between the first conductive lines 110 and the mold stack MS. The second conductive lines 120 may be two-dimensionally arranged on the plane (e.g., the XY plane) parallel to the top surface of the substrate 100. For example, the second conductive lines 120 may extend in the second direction X and may be arranged along the first direction Y to be spaced apart from one another. For example, the second conductive lines 120 may extend longitudinally in the second direction X. The second conductive lines 120 may be provided as selection lines (e.g., the selection lines SL of FIG. 1).

The selection channel patterns 130 may intersect the second conductive lines 120. For example, the selection channel patterns 130 may extend in a third direction Z, which intersects the top surface of the substrate 100, and may penetrate (i.e., extend into) the second conductive lines 120. That is, the selection channel patterns 130 may extend into the second conductive lines 120 in the third direction Z. For example, the third direction Z may be perpendicular to the top surface of the substrate 100. The third direction Z may also be referred to as a vertical direction. The first direction Y, the second direction X, and the third direction Z may intersect each other. The selection channel patterns 130 may connect the first conductive lines 110 to the conductive pillars 160. For example, first ends (e.g., lower ends) of the selection channel patterns 130 may be connected to the first conductive lines 110, and second ends (e.g., upper ends) of the selection channel patterns 130 may be connected to the conductive pillars 160. It will be understood that “an element A connected to an element B” (or similar language) as used herein means that the element A is physically and/or electrically connected to the element B.

The selection channel patterns 130 may include a semiconductor material, such as monocrystalline Si, polycrystalline Si (or poly-Si), an organic semiconductor material, or carbon nanotubes (CNTs), but the present disclosure is not limited thereto.

In some embodiments, first contact patterns 115 may be formed between the first conductive lines 110 and the selection channel patterns 130. The first contact patterns 115 may electrically connect the first conductive lines 110 to the selection channel patterns 130. The first contact patterns 115 may include a conductive material, such as poly-Si doped with impurities or a metal, but the present disclosure is not limited thereto.

The selection gate dielectric films 125 may be interposed between the second conductive lines 120 and the selection channel patterns 130. For example, the selection gate dielectric films 125 may surround at least parts of the sides of the selection channel patterns 130, and the second conductive lines 120 may be formed on the outer sides of the selection gate dielectric films 125.

The selection gate dielectric films 125 may include at least one of silicon oxide, silicon nitride, silicon oxynitride, or a high-k material with a greater dielectric constant than silicon oxide, but the present disclosure is not limited thereto. The high-k material may include at least one of, for example, aluminum oxide, hafnium oxide, lanthanum oxide, tantalum oxide, titanium oxide, lanthanum hafnium oxide, lanthanum aluminum oxide, dysprosium scandium oxide, or a combination thereof.

The mold stack MS may be formed on the selection channel patterns 130. For example, a lower insulating film 105, which covers the first conductive lines 110, the second conductive lines 120, the selection gate dielectric films 125, and the selection channel patterns 130, may be formed on the substrate 100. The mold stack MS may be stacked on the lower insulating film 105. The lower insulating film 105 may include at least one of, for example, silicon oxide, silicon oxynitride, or a low-k material with a smaller dielectric constant than silicon oxide, but the present disclosure is not limited thereto.

The mold stack MS may include a plurality of mold insulating films 140 and a plurality of gate electrodes 150, which are stacked on the substrate 100. The mold insulating films 140 and the gate electrodes 150 may have a layered structure extending along the plane parallel to the top surface of the substrate 100. The mold insulating films 140 and the gate electrodes 150 may be alternately stacked on the substrate 100. The gate electrodes 150 may be sequentially stacked on the substrate 100 by being separated from one another by the mold insulating films 140. The gate electrodes 150 may be provided as wordlines (e.g., the wordlines WL of FIG. 1). The first conductive lines 110 may be spaced apart from the mold stack MS in the third direction Z, and the second conductive lines 120 may extend in the second direction X between the mold stack MS and the first conductive lines 110.

The gate electrodes 150 may include a conductive material, for example, a metal such as tungsten (W), molybdenum (Mo), ruthenium (Ru), cobalt (Co), or nickel (Ni) or a semiconductor material such as Si, but the present disclosure is not limited thereto. For example, the gate electrodes 150 may include at least one of W, Mo, or Ru. In another example, the gate electrodes 150 may include poly-Si.

In some embodiments, each of the gate electrodes 150 may include a sequential stack of a barrier metal film and a filling metal film. The barrier metal film may include a metal nitride film such as a titanium nitride (TiN) film. The filling metal film may fill the remaining portion of the respective gate electrode 150 that is not occupied by the barrier metal film.

The mold insulating films 140 may include at least one of, for example, silicon oxide, silicon nitride, or silicon oxynitride, but the present disclosure is not limited thereto. For example, each of the mold insulating films 140 may include a silicon oxide film.

The conductive pillars 160 may extend in the third direction Z, which intersects the top surface of the substrate 100, and may intersect the gate electrodes 150. For example, the conductive pillars 160 may be pillar-shaped structures (e.g., cylindrical structures) that penetrate (i.e., extend into) the mold stack MS and extend in the third direction Z. That is, the conductive pillars 160 may extend into the mold stack MS in the third direction Z. The conductive pillars 160 may be connected to the selection channel patterns 130. For example, first ends (e.g., lower ends) of the conductive pillars 160 may be connected to the selection channel patterns 130.

The conductive pillars 160 may include, for example, a metal such as W, Mo, Ru, Co, or Ni or a semiconductor material such as Si, but the present disclosure is not limited thereto.

In some embodiments, second contact patterns 135 may be formed between the selection channel patterns 130 and the conductive pillars 160. The second contact patterns 135 may electrically connect the selection channel patterns 130 to the conductive pillars 160. The second contact patterns 135 may include a conductive material, such as poly-Si doped with impurities or a metal, but the present disclosure is not limited thereto.

The conductive pillars 160 may be spaced apart from one another on the plane parallel to the top surface of the substrate 100. For example, as illustrated in FIG. 3, the conductive pillars 160 may include first and second conductive pillars 160A and 160B, which are spaced apart from each other in the second direction X. The first and second conductive pillars 160A and 160B may extend in the third direction Z and may intersect the gate electrodes 150.

In some embodiments, the conductive pillars 160 may be arranged in a zigzag pattern or a honeycomb pattern. For example, each pair of adjacent conductive pillars 160 may be staggered in the first and/or second directions Y and X. The conductive pillars 160 can further improve the integration density of the non-volatile memory device according to some embodiments of the present disclosure. The number and the layout of conductive pillars 160 are merely exemplary and are not particularly limited.

The information storage films 170 may be interposed between the conductive pillars 160 and their respective gate electrodes 150. For example, the information storage films 170 may surround at least parts of the sides of the conductive pillars 160, and the gate electrodes 150 may be formed on the outer sides of the information storage films 170. The information storage films 170 may also be referred to as an information storage film 170 in the singular.

The information storage films 170 may include chalcogenide. Chalcogenide refers to a compound that comprises at least one chalcogen element and at least one cationic element. For example, the information storage films 170 may include a compound formed by combining at least one chalcogen element, such as tellurium (Te), selenium (Se), or sulfur(S), with at least one element selected from among Ge, Sb, Bi, Pb, Sn, Ag, As, Si, In, Ti, Ga, P, O, and C.

In some embodiments, the information storage films 170 may include a chalcogenide component containing Se, arsenic (As), and germanium (Ge), i.e., a SeAsGe alloy. In some embodiments, the SeAsGe alloy may further include Si or indium (In). In some embodiments, the SeAsGe alloy may further include hydrogen (H), oxygen (O), nitrogen (N), chlorine (Cl), or fluorine (F).

In some embodiments, the information storage films 170 may be controlled to have different threshold voltages during a normal operation of the nonvolatile memory device. For example, the chalcogenide compound included in the information storage films 170 may have first and second threshold voltages, which are different, depending on a bias applied to the information storage films 170. The first threshold voltage may correspond to a first logic state of data storage elements, for example, a logic value of 0, and the second threshold volage may correspond to a second logic state of data storage elements, for example, a logic value of 1. The difference between the first and second threshold voltages may be defined as the read window (RW) of the nonvolatile memory device according to some embodiments of the present disclosure. The nonvolatile memory device including the information storage films 170 may be provided as a selector-only memory (SOM) or a self-selecting memory (SSM).

The information storage films 170 may be interposed between the mold stack MS and the conductive pillars 160. For example, as illustrated in FIG. 3, the information storage films 170 may include a first information storage film 170A, which is interposed between the mold stack MS and the first conductive pillar 160A, and a second information storage film 170B, which is interposed between the mold stack MS and the second conductive pillar 160B. The first information storage film 170A may be interposed between the first conductive pillar 160A and its respective gate electrode(s) 150, and the second information storage film 170B may be interposed between the second conductive pillar 160B and its respective gate electrode(s) 150. The first and second information storage films 170A and 170B may also be referred to as an information storage film 170A/170B in the singular.

The charge dissipation layers 180 may be formed on the conductive pillars 160. For example, the charge dissipation layers 180 may be on (e.g., may cover) the top surfaces of the conductive pillars 160. Also, the charge dissipation layers 180 may be interposed between the conductive pillars 160 and the conductive layer 190.

The charge dissipation layers 180 may include an insulating material, for example, at least one of silicon oxide, silicon nitride, or silicon oxynitride, but the present disclosure is not limited thereto. In some embodiments, the charge dissipation layers 180 may include an oxide-based material. For example, the charge dissipation layers 180 may include silicon oxide films.

In some embodiments, the charge dissipation layers 180 may be spaced apart from one another on the plane parallel to the top surface of the substrate 100. For example, as illustrated in FIG. 3, the charge dissipation layers 180 may include first and second charge dissipation layers 180A and 180B, which are spaced apart from each other in the second direction X. The first charge dissipation layer 180A may be interposed between the first conductive pillar 160A and the conductive layer 190, and the second charge dissipation layer 180B may be interposed between the second conductive pillar 160B and the conductive layer 190.

In some embodiments, the charge dissipation layers 180 may be separated from one another by an uppermost mold insulating film 140T, which is positioned at the top of the stack of the mold insulating films 140. For example, at least part of the uppermost mold insulating film 140T may be interposed between the first and second charge dissipation layers 180A and 180B.

The top surfaces of the charge dissipation layers 180 are illustrated as being coplanar with the top surface of the uppermost mold insulating film 140T, but the present disclosure is not limited thereto. For example, the top surfaces of the charge dissipation layers 180 may be formed to be higher or lower than the top surface of the uppermost mold insulating film 140T in the third direction Z (e.g., relative to the top surface of the substrate 100).

In some embodiments, a thickness DI (e.g., in the third direction Z) of the charge dissipation layers 180 may be less than a thickness D2 (e.g., in the third direction Z) of the uppermost mold insulating film 140T.

In some embodiments, each of the charge dissipation layers 180 may include first and second oxide layers 182 and 184. The first oxide layer 182 may include an oxide of the material of the conductive pillars 160. That is, the first oxide layer 182 may include an oxide of a material included in the conductive pillars 160. For example, the first oxide layer 182 may include an oxide film formed as a result of the oxidation of part (e.g., an upper portion) of its respective conductive pillar 160. The second oxide layer 184 may include an oxide of the material of the information storage films 170. That is, the second oxide layer 184 may include an oxide of a material included in the information storage films 170. For example, the second oxide layer 184 may include an oxide film formed as a result of the oxidation of part (e.g., an upper portion) of its respective information storage film 170.

The conductive layer 190 may be formed on the charge dissipation layers 180. For example, the conductive layer 190 may extend along the top surface of the mold stack MS and the top surfaces of the charge dissipation layers 180. The conductive layer 190 may be spaced apart from the conductive pillars 160 by the charge dissipation layers 180. The conductive layer 190 may be spaced apart from the gate electrodes 150 in the third direction Z. The conductive layer 190 may be in the shape of a plate covering the mold stack MS and the charge dissipation layers 180, but the present disclosure is not limited thereto. Alternatively, a plurality of conductive layers 190, respectively corresponding to the charge dissipation layers 180, may be formed to be spaced apart from one another.

The conductive layer 190 may include a conductive material, such as W, Mo, Ru, Co, Ni, aluminum (Al), tin (Sn), titanium (Ti), or graphene, but the present disclosure is not limited thereto.

In some embodiments, at least some of the conductive pillars 160 may be electrically floated during a variety of operations of the nonvolatile memory device. For example, transistors including the second conductive lines 120 and the selection channel patterns 130 may be provided as selection transistors choosing at least some of the conductive pillars 160 to perform a program operation or a read operation on particular data storage elements. Specifically, selection transistors corresponding to selected conductive pillars 160 may be turned on and electrically connect the first conductive lines 110 to the selected conductive pillars 160. Selection transistors corresponding to some non-selected conductive pillars 160 may be turned off and electrically float the corresponding non-selected conductive pillars 160. The electrically floated non-selected conductive pillars 160 can reduce waste of power from voltage swings and can thereby enhance the performance of the nonvolatile memory device according to some embodiments of the present disclosure.

In order to perform a program operation or a read operation on the particular data storage elements, a bias may be applied to particular gate electrodes 150. Since the conductive pillars 160 penetrate (i.e., extend into) the gate electrodes 150 by extending in the third direction Z, the selected conductive pillars 160 and the non-selected conductive pillars 160 may share the same gate electrodes 150. As a result, the bias applied to the gate electrodes 150 may induce uncertain charge accumulation in the non-selected conductive pillars 160 due to capacitive coupling or leakage coupling. The uncertain accumulated charge in the non-selected conductive pillars 160 may cause disturbances in the stored state of the data storage elements, potentially degrading the performance and reliability of the nonvolatile memory device according to some embodiments of the present disclosure.

The charge dissipation layers 180 and the conductive layer 190 may dissipate the charge accumulated in the electrically floated conductive pillars 160 or equalize the voltage applied to the conductive pillars 160. Specifically, the charge dissipation layers 180 may be configured to form dissipative coupling between the conductive pillars 160 and the conductive layer 190. For example, a ground voltage or another voltage (e.g., an equalization voltage) may be applied to the conductive layer 190, and dissipative coupling may be caused between the conductive pillars 160 and the conductive layer 190 through the charge dissipation layers 180 due to resistive impedance and/or capacitive impedance. This dissipative coupling can improve the performance and reliability of the nonvolatile memory device according to some embodiments of the present disclosure by dissipating or equalizing the difference in voltage between the conductive pillars 160 and the conductive layer 190.

By spacing apart the charge dissipation layers 180, disturbances between neighboring conductive pillars 160 can be prevented. Specifically, as discussed earlier, the first and second charge dissipation layers 180A and 180B, which correspond to the first and second conductive pillars 160A and 160B, respectively, may be formed to be separated from each other. Consequently, when the charge accumulated in the first conductive pillar 160A and/or the second conductive pillar 160B is dissipated or equalized through dissipative coupling, disturbances between the first and second conductive pillars 160A and 160B can be prevented. In this manner, a nonvolatile memory device with a further improved performance and reliability can be provided.

Referring to FIG. 4, the nonvolatile memory device according to some embodiments of the present disclosure may further include first barrier layers 172 and second barrier layers 174.

The first barrier layers 172 may be interposed between the information storage films 170 and their respective gate electrodes 150. For example, the first barrier layers 172 may surround at least parts of the outer sides of the information storage films 170, and the gate electrodes 150 may be formed on the outer sides of the first barrier layers 172.

The second barrier layers 174 may be interposed between the information storage films 170 and their respective conductive pillars 160. For example, the second barrier layers 174 may surround at least parts of the outer sides of the conductive pillars 160, and the information storage films 170 may be formed on the outer sides of the second barrier layers 174.

The first barrier layers 172 and the second barrier layers 174 may protect the information storage films 170. The first barrier layers 172 and the second barrier layers 174 may include, for example, carbon layers, but the present disclosure is not limited thereto.

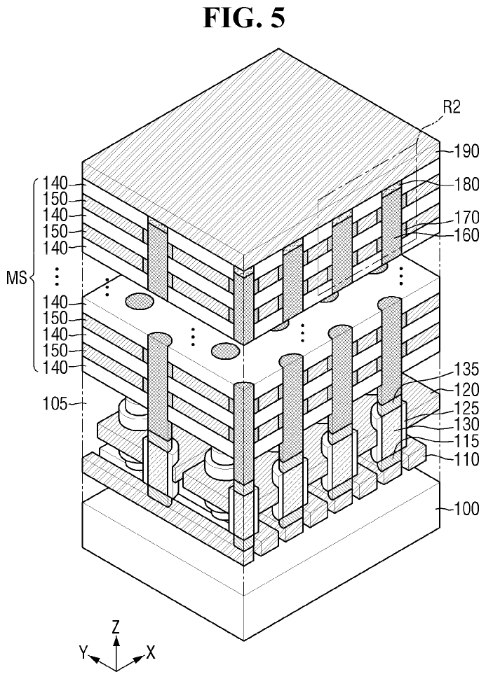

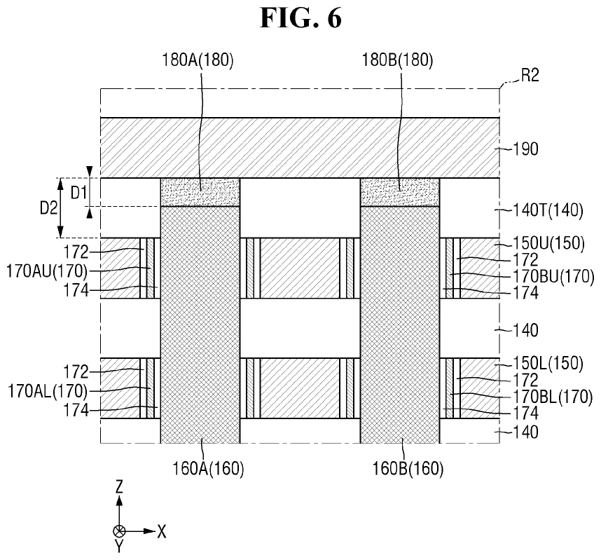

FIG. 5 is an exploded perspective view of a nonvolatile memory device according to some embodiments of the present disclosure. FIG. 6 is an enlarged cross-sectional view of a region R2 of FIG. 5. For convenience of description, redundant or repetitive portions that overlap with the content described earlier with reference to FIGS. 1 through 4 will be briefly mentioned or omitted.

Referring to FIGS. 5 and 6, information storage films 170 may be separated from one another in a third direction Z.

For example, as illustrated in FIG. 6, a plurality of gate electrodes 150 may include first and second wordlines 150L and 150U. The information storage films 170 may include a first sub-storage film 170AL, which is interposed between a first conductive pillar 160A and the first wordline 150L, and a second sub-storage film 170AU, which is interposed between the first conductive pillar 160A and the second wordline 150U. The information storage films 170 may also include a third sub-storage film 170BL, which is interposed between a second conductive pillar 160B and the first wordline 150L, and a fourth sub-storage film 170BU, which is interposed between the second conductive pillar 160B and the second wordline 150U. The first and second sub-storage films 170AL and 170AU may be spaced apart from each other in the third direction Z, and the third and fourth sub-storage films 170BL and 170BU may be spaced apart from each other in the third direction Z.

In some embodiments, the information storage films 170 may be separated from one another by the mold insulating films 140 in the third direction Z. For example, the mold insulating films 140 may protrude beyond the gate electrodes 150 toward the conductive pillars 160 (e.g., in the first direction Y and/or the second direction X). The information storage films 170 may be formed in regions that are created by the protrusion of the mold insulating films 140 between the gate electrodes 150 and the conductive pillars 160. Accordingly, the mold insulating films 140 may separate the first and second sub-storage films 170AL and 170AU in the third direction Z and may also separate the third and fourth sub-storage films 170BL and 170BU in the third direction Z.

In some embodiments, the first barrier layers 172 may be separated from one another in the third direction Z. For example, similar to the information storage films 170, the first barrier layers 172 may be separated from one another by the mold insulating films 140 in the third direction Z. The second barrier layers 174 are also illustrated as being separated from one another in the third direction Z, but the present disclosure is not limited thereto. For example, unlike the information storage films 170 and the first barrier layers 172, the second barrier layers 174 may not be separated from one another by the mold insulating films 140 in the third direction Z. For example, as illustrated in FIG. 4, the second barrier layers 174 may extend longitudinally along the sides of the conductive pillars 160 in the third direction Z.

In some embodiments, charge dissipation layers 180 may include an oxide of the material of the conductive pillars 160. That is, the charge dissipation layers 180 may include an oxide of a material included in the conductive pillars 160. For example, a first charge dissipation layer 180A may include an oxide film formed as a result of the oxidation of part (e.g., an upper portion) of the first conductive pillar 160A, and a second charge dissipation layer 180B may include an oxide film formed as a result of the oxidation of part (e.g., an upper portion) of the second conductive pillar 160B.

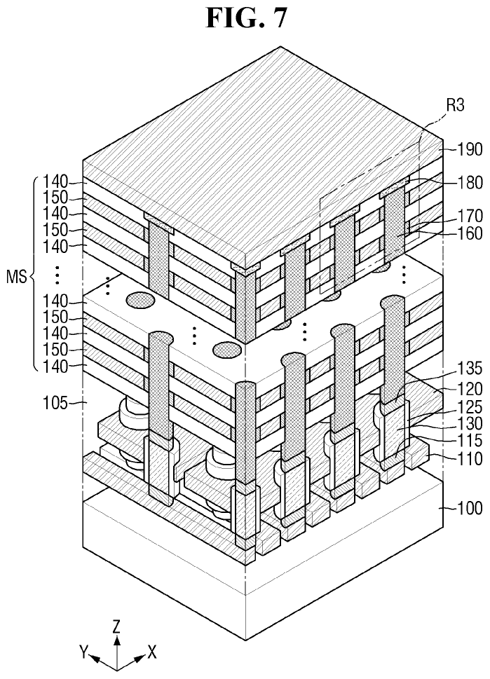

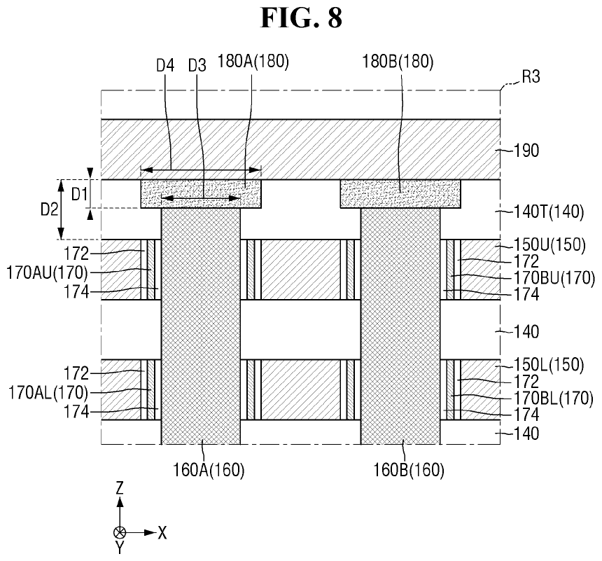

FIG. 7 is an exploded perspective view of a nonvolatile memory device according to some embodiments of the present disclosure. FIG. 8 is an enlarged cross-sectional view of a region R3 of FIG. 7. For convenience of description, redundant or repetitive portions that overlap with the content described earlier with reference to FIGS. 1 through 6 will be briefly mentioned or omitted.

Referring to FIGS. 7 and 8, the top surfaces of charge dissipation layers 180 may be coplanar with the top surface of an uppermost mold insulating film 140T.

For example, recesses may be formed on conductive pillars 160, and charge dissipation layers 180 may be formed to fill the recesses. The charge dissipation layers 180, filling the recesses, may include an insulating material, for example, at least one of silicon oxide, silicon nitride, or silicon oxynitride, but the present disclosure is not limited thereto. For example, the charge dissipation layers 180 may include silicon oxide films.

A width D4 of the charge dissipation layers 180 may be greater than a width D3 of the conductive pillars 160, but the present disclosure is not limited thereto. Alternatively, the width D4 of the charge dissipation layers 180 may be the same as the width D3 of the conductive pillars 160. Here, the term “width” refers to the dimension measured on the plane parallel to the top surface of a substrate 100. Moreover, in this specification, the term “same” or “identical” encompasses not only complete identity but also minor variances that may arise due to process margins or other factors.

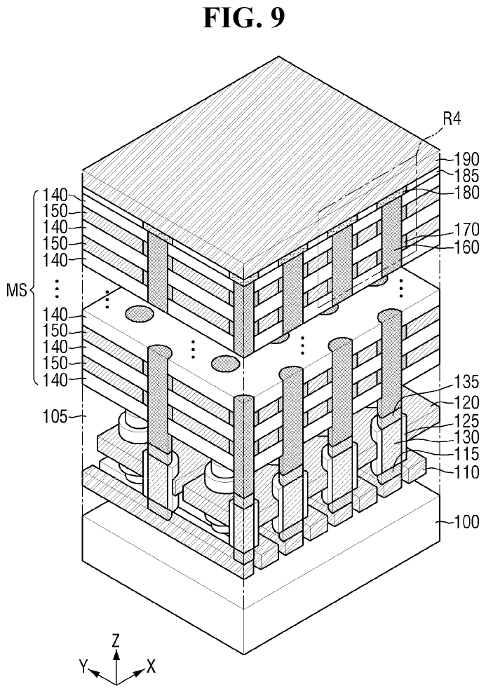

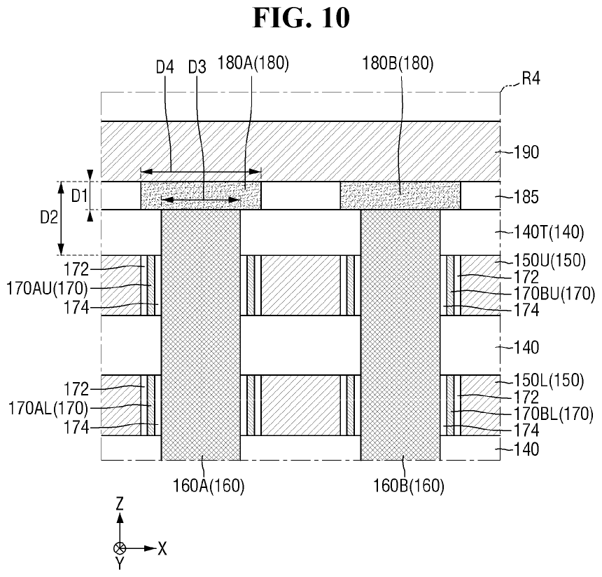

FIG. 9 is an exploded perspective view of a nonvolatile memory device according to some embodiments of the present disclosure. FIG. 10 is an enlarged cross-sectional view of a region R4 of FIG. 9. For convenience of description, redundant or repetitive portions that overlap with the content described earlier with reference to FIGS. 1 through 8 will be briefly mentioned or omitted.

Referring to FIGS. 9 and 10, a plurality of charge dissipation layers 180 may be separated from one another by a filling insulating film 185.

The filling insulating film 185 may be formed on a mold stack MS. For example, the filling insulating film 185 may extend along the top surface of the mold stack MS. The filling insulating film 185 may be interposed between the charge dissipation layers 180 to separate the charge dissipation layers 180 from one another. For example, the filling insulating film 185 may be interposed between first and second charge dissipation layers 180A and 180B.

The filling insulating film 185 may include at least one of, for example, silicon oxide, silicon nitride, or silicon oxynitride, but the present disclosure is not limited thereto.

A conductive layer 190 may be formed on the charge dissipation layers 180 and the filling insulating film 185. For example, the conductive layer 190 may extend along the top surfaces of the charge dissipation layers 180 and the top surface of the filling insulating film 185.

In some embodiments, the top surface of the filling insulating film 185 may be coplanar with the top surfaces of the charge dissipation layers 180.

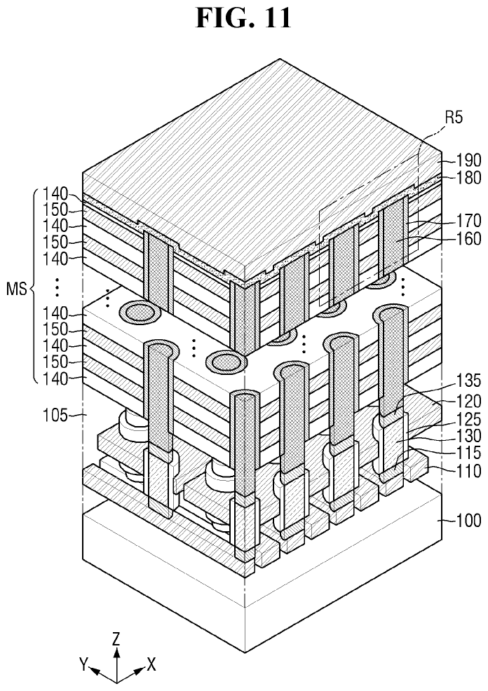

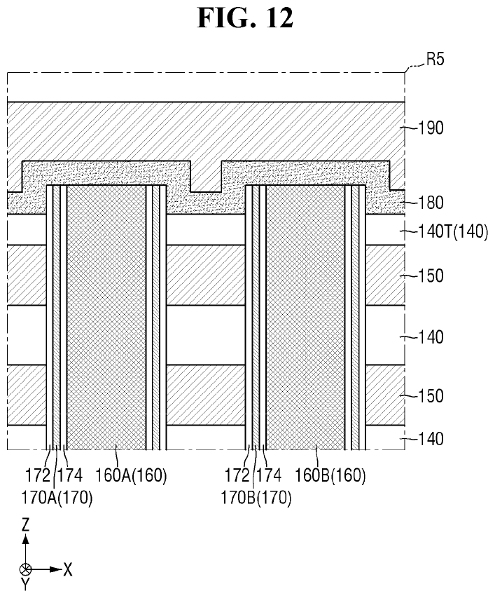

FIG. 11 is an exploded perspective view of a nonvolatile memory device according to some embodiments of the present disclosure. FIG. 12 is an enlarged cross-sectional view of a region R5 of FIG. 11. For convenience of description, redundant or repetitive portions that overlap with the content described earlier with reference to FIGS. 1 through 4 will be briefly mentioned or omitted.

Referring to FIGS. 11 and 12, conductive pillars 160 may protrude beyond the top surface of a mold stack MS (e.g., in the third direction Z).

For example, the top surfaces of the conductive pillars 160 may be formed to be higher than the top surface of an uppermost mold insulating film 140T in the third direction Z (e.g., relative to the top surface of the substrate 100). In some embodiments, the top surfaces of information storage films 170 may also be formed to be higher than the top surface of the uppermost mold insulating film 140T in the third direction Z (e.g., relative to the top surface of the substrate 100). In some embodiments, the top surfaces of first barrier layers 172 and/or the top surfaces of second barrier layers 174 may also be formed to be higher than the top surface of the uppermost mold insulating film 140T in the third direction Z (e.g., relative to the top surface of the substrate 100).

In some embodiments, charge dissipation layers 180 may be on (e.g., may cover) the mold stack MS and the conductive pillars 160. For example, the charge dissipation layers 180 may extend conformally along profiles of the top surface of the uppermost mold insulating film 140T and the top surfaces of the conductive pillars 160. The charge dissipation layers 180 can reduce disturbances between neighboring conductive pillars 160 by increasing electrical paths between the conductive pillars 160.

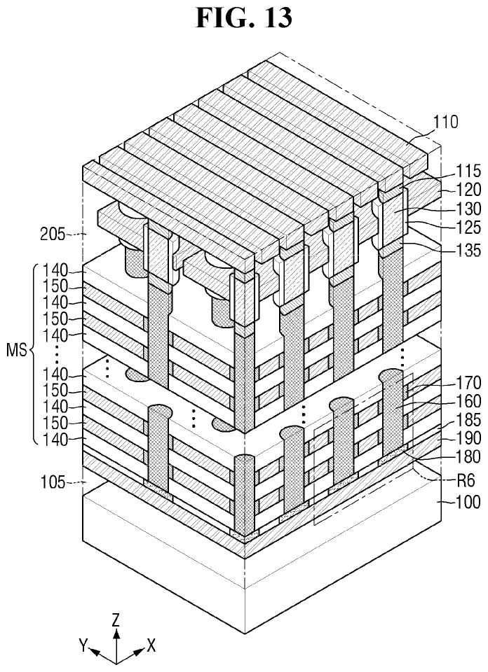

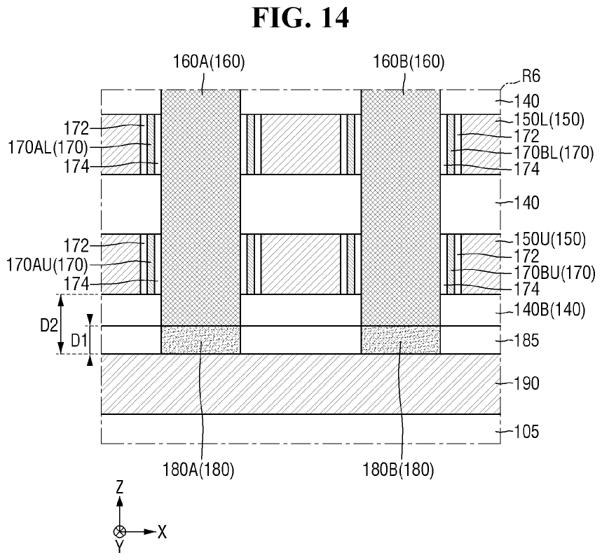

FIG. 13 is an exploded perspective view of a nonvolatile memory device according to some embodiments of the present disclosure. FIG. 14 is an enlarged cross-sectional view of a region R6 of FIG. 13. For convenience of description, redundant or repetitive portions that overlap with the content described earlier with reference to FIGS. 1 through 10 will be briefly mentioned or omitted.

Referring to FIGS. 13 and 14, charge dissipation layers 180 and a conductive layer 190 may be interposed between a substrate 100 and a mold stack MS.

For example, the conductive layer 190 may be stacked on a lower insulating film 105. The charge dissipation layers 180 may be stacked on the conductive layer 190. In some embodiments, a filling insulating film 185 may be formed on the conductive layer 190, and the charge dissipation layers 180 may be separated from one another by the filling insulating film 185. The conductive layer 190 may be between the substrate 100 and a plurality of gate electrodes 150.

In some embodiments, the mold stack MS may be interposed between the substrate 100 and first conductive lines 110. For example, second conductive lines 120, which extend in a second direction X, may be formed on the mold stack MS. Selection channel patterns 130, which extend in a third direction Z and are connected to conductive pillars 160 by penetrating (i.e., extending into) the second conductive lines 120, may be formed. Selection gate dielectric films 125, which are interposed between the second conductive lines 120 and the selection channel patterns 130, may be formed. First conductive lines 110, which extend in a first direction Y and are connected to the selection channel patterns 130, may be formed.

An upper insulating film 205, which covers the first conductive lines 110, the second conductive lines 120, the selection gate dielectric films 125, and the selection channel patterns 130, may be formed on the mold stack MS. The upper insulating film 205 may include at least one of, for example, silicon oxide, silicon oxynitride, or a low-k material with a smaller dielectric constant than silicon oxide, but the present disclosure is not limited thereto.

Methods of fabricating nonvolatile memory devices according to some embodiments of the present disclosure will hereinafter be described with reference to FIGS. 1 through 35.

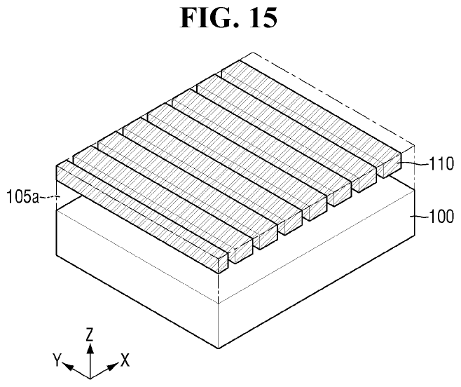

FIGS. 15 through 22 are perspective views illustrating intermediate steps of a method of fabricating a nonvolatile memory device according to some embodiments of the present disclosure. For convenience of description, redundant or repetitive portions that overlap with the content described earlier with reference to FIGS. 1 through 14 will be briefly mentioned or omitted.

Referring to FIG. 15, first conductive lines 110 are formed on a substrate 100.

For example, a first interlayer insulating film 105a may be formed on the substrate 100. The first conductive lines 110 may be formed in the first interlayer insulating film 105a. The first conductive lines 110 may be insulated from one another by the first interlayer insulating film 105a.

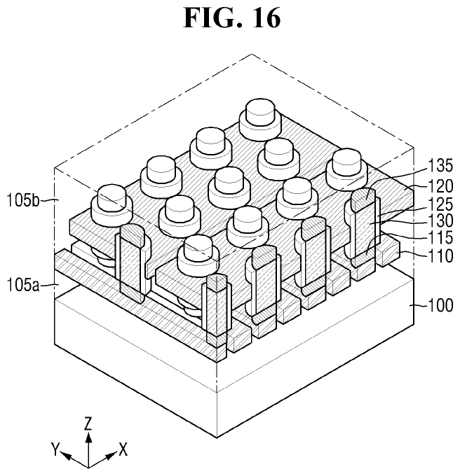

Referring to FIG. 16, second conductive lines 120, selection gate dielectric films 125, and selection channel patterns 130 are formed on the first conductive lines 110.

For example, the second conductive lines 120, which extend in a second direction X, may be formed on the first conductive lines 110. Thereafter, the selection channel patterns 130, which extend in a third direction Z and are connected to the first conductive lines 110 by penetrating (i.e., extending into) the second conductive lines 120, and the selection gate dielectric films 125, which are interposed between the second conductive lines 120 and the selection channel patterns 130, may be formed.

A second interlayer insulating film 105b, which covers the second conductive lines 120, the selection gate dielectric films 125, and the selection channel patterns 130, may be formed on the first conductive lines 110 and the first interlayer insulating film 105a. In this manner, a lower insulating film 105, which includes the first and second interlayer insulating films 105a and 105b, may be formed.

In some embodiments, first contact patterns 115 may be formed between the first conductive lines 110 and the selection channel patterns 130.

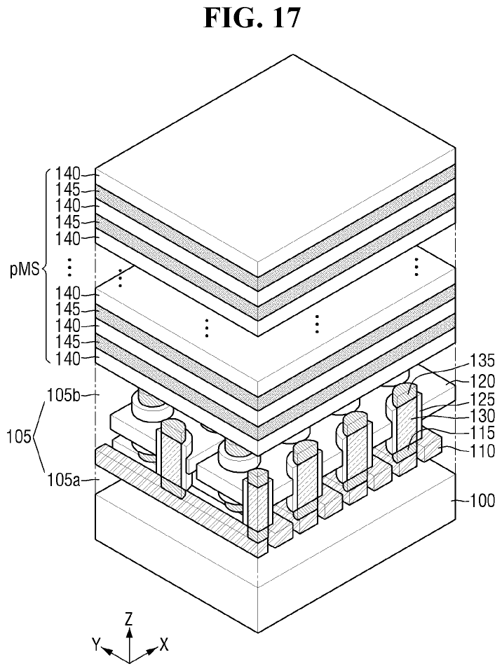

Referring to FIG. 17, a preliminary mold pMS is formed on the lower insulating film 105.

The preliminary mold pMS may include a plurality of mold insulating films 140 and a plurality of mold sacrificial films 145, which are stacked on the lower insulating film 105. The mold insulating films 140 and the mold sacrificial films 145 may have a layered structure extending along a plane (e.g., an XY plane) parallel to the top surface of the substrate 100. The mold insulating films 140 and the mold sacrificial films 145 may be alternately stacked on the substrate 100.

The mold sacrificial films 145 may include a material with an etching selectivity with respect to the mold insulating films 140. For example, the mold insulating films 140 may include silicon oxide films, and the mold sacrificial films 145 may include silicon nitride films.

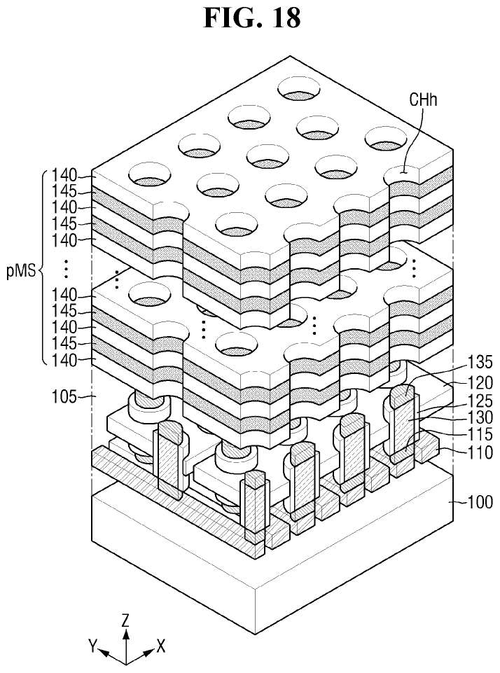

Referring to FIG. 18, a plurality of through holes CHh are formed in the preliminary mold pMS.

The through holes CHh may penetrate (i.e., extend into) the preliminary mold pMS by extending in the third direction Z. The through holes CHh may be spaced apart from one another on the plane parallel to the top surface of the substrate 100. In some embodiments, the through holes CHh may be arranged in a zigzag pattern or a honeycomb pattern.

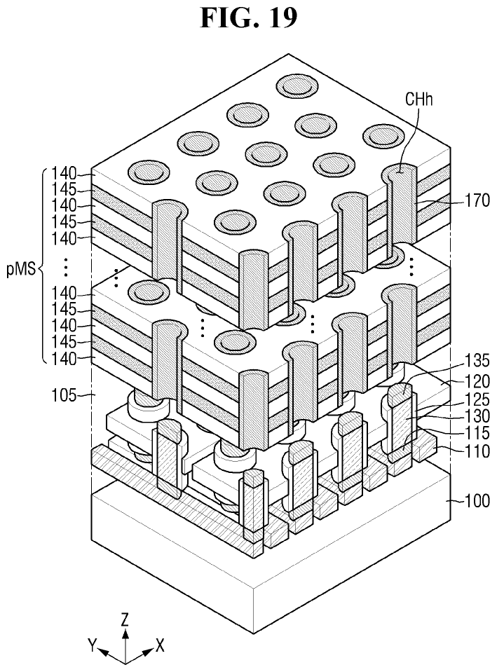

Referring to FIG. 19, information storage films 170 are formed in the through holes CHh.

The information storage films 170 may extend along the sides of the through holes CHh. In some embodiments, the information storage films 170 may extend conformally along the profiles of the sides of the through holes CHh.

The information storage films 170 may include chalcogenide. In some embodiments, the information storage films 170 may include a chalcogenide component containing Se, As, and Ge, i.e., a SeAsGe alloy.

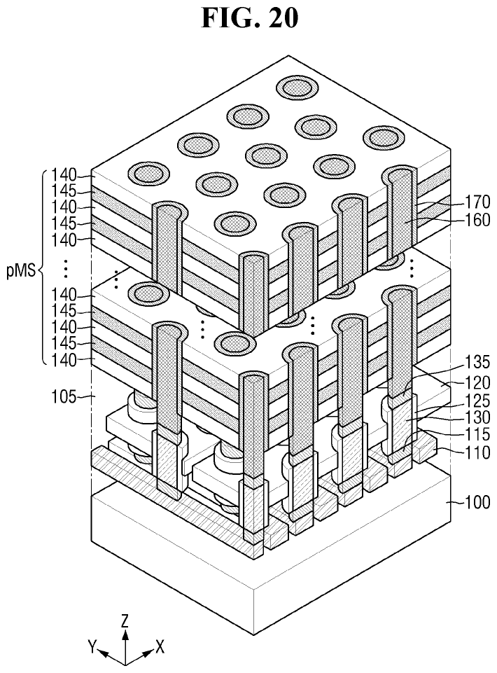

Referring to FIGS. 19 and 20, conductive pillars 160 are formed in the through holes CHh.

The conductive pillars 160 may fill the remaining portion of the respective through holes CHh that are not occupied by the information storage films 170. The conductive pillars 160 may extend in the third direction Z and may intersect the mold sacrificial films 145. The conductive pillars 160 may be connected to the selection channel patterns 130.

In some embodiments, second contact patterns 135 may be formed between the selection channel patterns 130 and the conductive pillars 160.

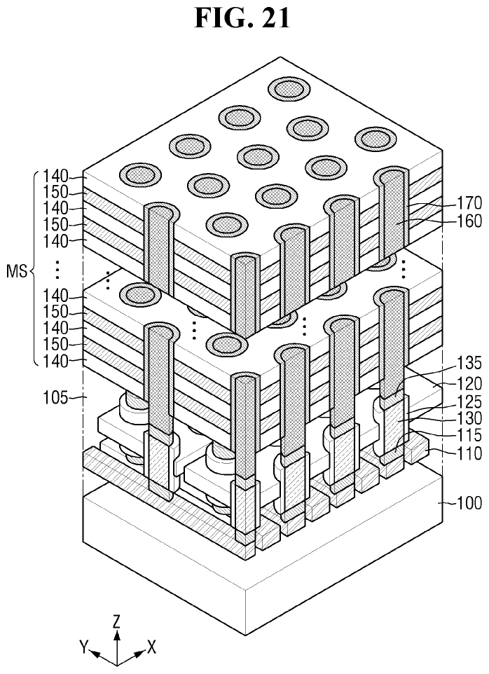

Referring to FIGS. 20 and 21, a plurality of gate electrodes 150, which replace the mold sacrificial films 145, are formed.

For example, the mold sacrificial films 145 may be removed. As the mold sacrificial films 145 have an etching selectivity with respect to the mold insulating films 140, the mold sacrificial films 145 may be selectively removed. Thereafter, the gate electrodes 150, which replace the mold sacrificial films 145, may be formed. Accordingly, a mold stack MS including the mold insulating films 140 and the gate electrodes 150 that are alternately stacked on the substrate 100 may be formed.

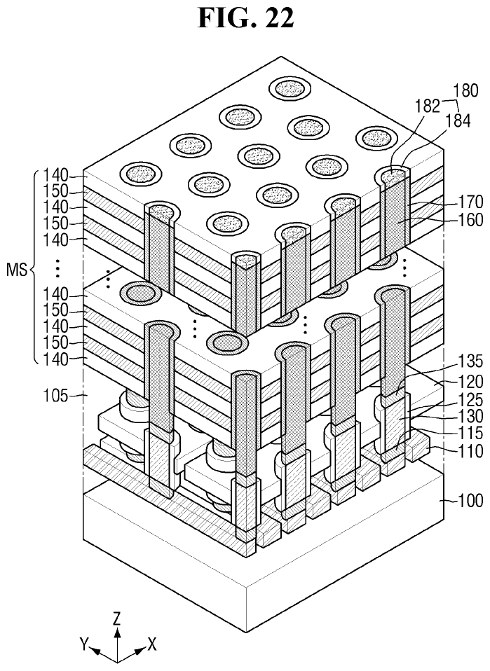

Referring to FIG. 22, an oxidation process may be performed on upper portions of the conductive pillars 160.

The upper portions of the conductive pillars 160 are oxidated by the oxidation process, and as a result, a plurality of charge dissipation layers 180 may be formed. Since the conductive pillars 160 are spaced apart from one another on the plane parallel to the top surface of the substrate 100, the charge dissipation layers 180, which correspond to the conductive pillars 160, may also be spaced apart from one another. For example, the charge dissipation layers 180 may be separated from one another by an uppermost mold insulating film among the mold insulating films 140. That is, the charge dissipation layers 180 may be separated from one another by an uppermost one of the mold insulating films 140.

In some embodiments, upper portions of the information storage films 170 may also be oxidated by the oxidation process. As a result, charge dissipation layers 180 including first oxide layers 182 and second oxide layers 184 may be formed.

Thereafter, referring again to FIG. 2, a conductive layer 190 is formed on the mold stack MS and the charge dissipation layers 180. In this manner, the nonvolatile memory device of FIGS. 2 and 3 may be fabricated.

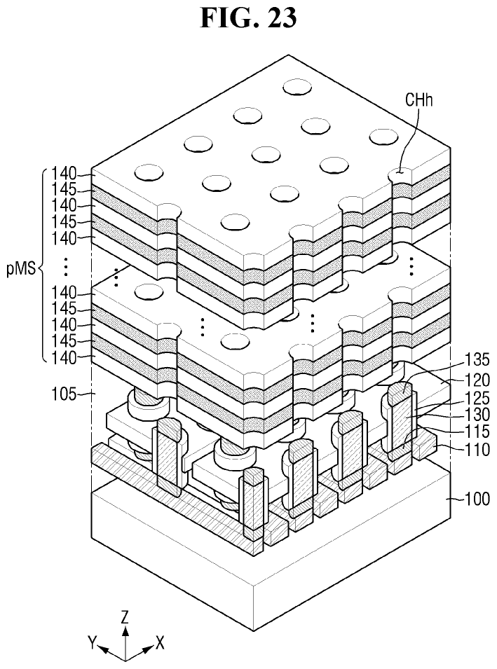

FIGS. 23 through 28 are perspective views illustrating intermediate steps of a method of fabricating a nonvolatile memory device according to some embodiments of the present disclosure. For convenience of description, redundant or repetitive portions that overlap with the content described earlier with reference to FIGS. 1 through 22 will be briefly mentioned or omitted. Specifically, FIG. 23 illustrates an intermediate step to be performed after that depicted in FIG. 17.

Referring to FIG. 23, a plurality of through holes CHh are formed in a preliminary mold pMS. The formation of the through holes CHh is as described earlier with reference to FIG. 18, and thus a detailed description thereof will be omitted.

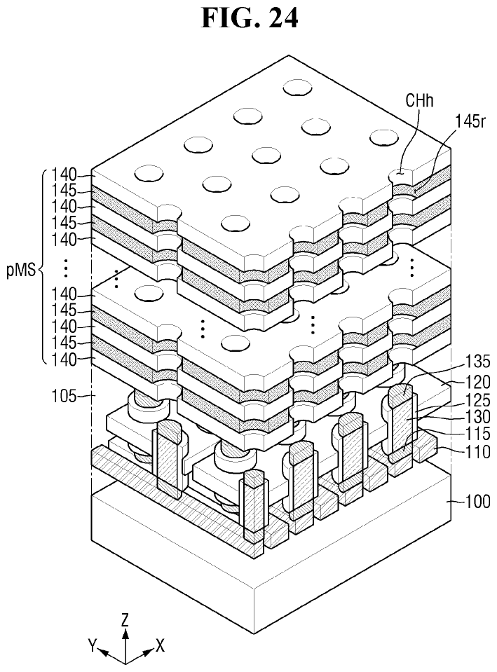

Referring to FIG. 24, a first recess process is performed on mold sacrificial films 145.

As a result of the first recess process, the mold sacrificial films 145, exposed by the through holes CHh, may be recessed. As the mold sacrificial films 145 have an etching selectivity with respect to the mold insulating films 140, the mold sacrificial films 145 may be selectively recessed. Consequently, first recesses 145r may be formed between the through holes CHh and their respective mold sacrificial films 145. The mold insulating films 140 may protrude beyond the mold sacrificial films 145 toward the through holes CHh.

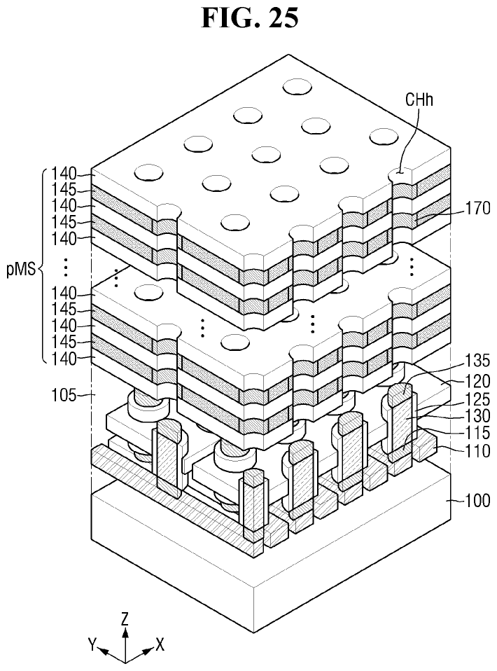

Referring to FIGS. 24 and 25, information storage films 170 are formed in the first recesses 145r.

For example, chalcogenide films, which fill the first recesses 145r, may be formed in the through holes CHh. Thereafter, a second recess process may be performed on the chalcogenide film. As a result of the second recess process, the information storage films 170 may be separated from one another by mold insulating films 140 in a third direction Z. For example, the second recess process may be continued until the sides of the mold insulating films 140 are exposed.

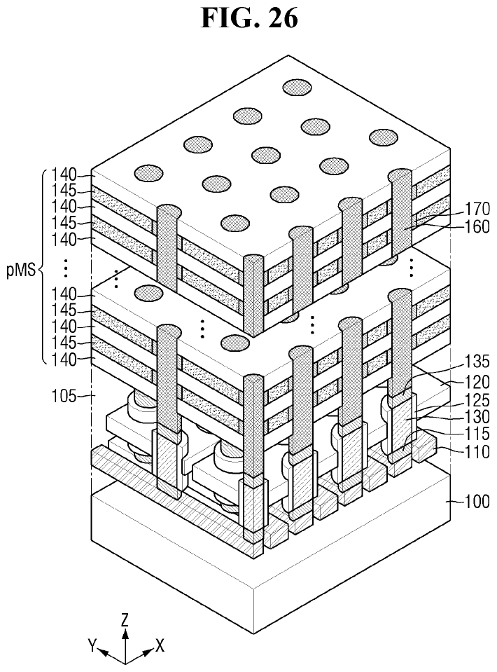

Referring to FIGS. 25 and 26, conductive pillars 160 are formed in the through holes CHh. The formation of the conductive pillars 160 is as described earlier with reference to FIG. 20, and thus a detailed description thereof will be omitted.

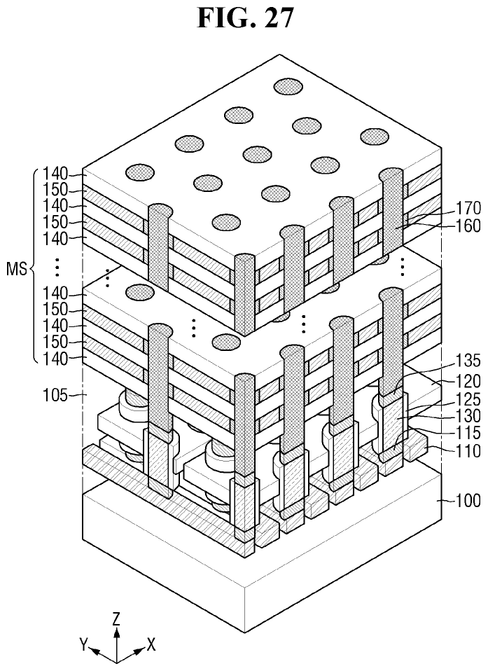

Referring to FIGS. 26 and 27, a plurality of gate electrodes 150, which replace the mold sacrificial films 145, are formed. The formation of the gate electrodes 150 is as described earlier with reference to FIG. 21, and thus a detailed description thereof will be omitted.

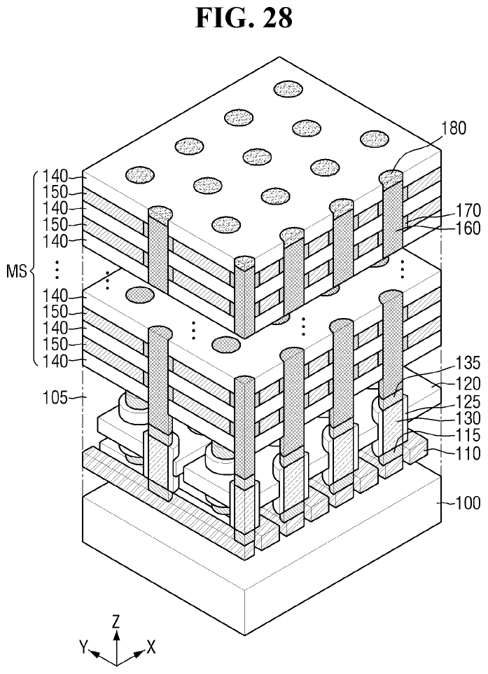

Referring to FIG. 28, an oxidation process may be performed on upper portions of the conductive pillars 160. As a result, a plurality of charge dissipation layers 180 may be formed. The oxidation process is as described earlier with reference to FIG. 22, and thus a detailed description thereof will be omitted.

Thereafter, referring again to FIG. 5, a conductive layer 190 is formed on the mold stack MS and the charge dissipation layers 180. In this manner, the nonvolatile memory device of FIGS. 5 and 6 may be fabricated.

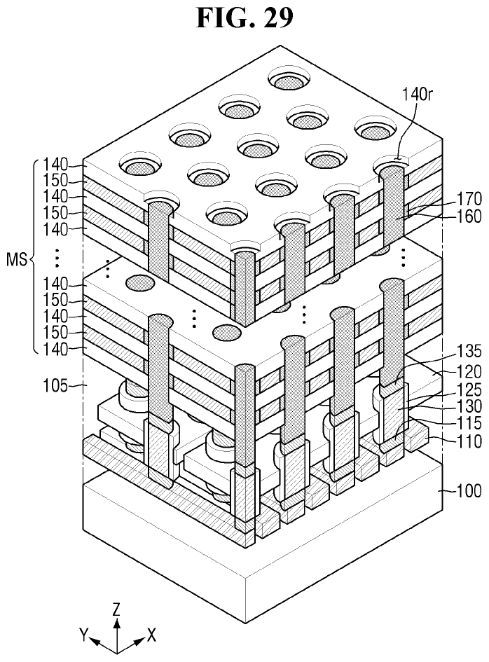

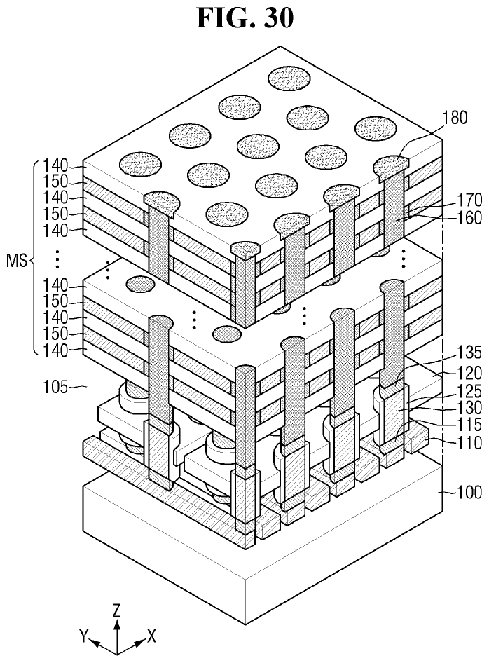

FIGS. 29 and 30 are perspective views illustrating intermediate steps of a method of fabricating a nonvolatile memory device according to some embodiments of the present disclosure. For convenience of description, redundant or repetitive portions that overlap with the content described earlier with reference to FIGS. 1 through 28 will be briefly mentioned or omitted. Specifically, FIG. 29 illustrates an intermediate step to be performed after that depicted in FIG. 27.

Referring to FIG. 29, a first etch-back process is performed on conductive pillars 160.

As a result of the first etch-back process, second recesses 140r may be formed on the top surfaces of the conductive pillars 160. As the conductive pillars 160 are spaced apart from one another on a plane (e.g., an XY plane) that is parallel to the top surface of a substrate 100, the second recesses 140r, which correspond to the conductive pillars 160, may also be spaced apart from one another.

The width of the second recesses 140r (e.g., in the first direction Y and/or the second direction X) may be greater than the width of the conductive pillars 160 (e.g., in the first direction Y and/or the second direction X), but the present disclosure is not limited thereto. Alternatively, the width of the second recesses 140r may be the same as the width of the conductive pillars 160.

Referring to FIGS. 29 and 30, charge dissipation layers 180, which fill the second recesses 140r, are formed.

As the second recesses 140r are spaced apart from one another on the plane parallel to the top surface of the substrate 100, the charge dissipation layers 180, which correspond to the conductive pillars 160, may also be spaced apart from one another. For example, the charge dissipation layers 180 may be separated from one another by an uppermost mold insulating film among the mold insulating films 140. That is, the charge dissipation layers 180 may be separated from one another by an uppermost one of the mold insulating films 140.

The charge dissipation layers 180 may include an insulating material, for example, at least one of silicon oxide, silicon nitride, or silicon oxynitride, but the present disclosure is not limited thereto. In some embodiments, the charge dissipation layers 180 may include an oxide-based material. For example, the charge dissipation layers 180 may include silicon oxide films.

Thereafter, referring again to FIG. 7, a conductive layer 190 is formed on a mold stack MS and the charge dissipation layers 180. In this manner, the nonvolatile memory device of FIGS. 7 and 8 may be fabricated.

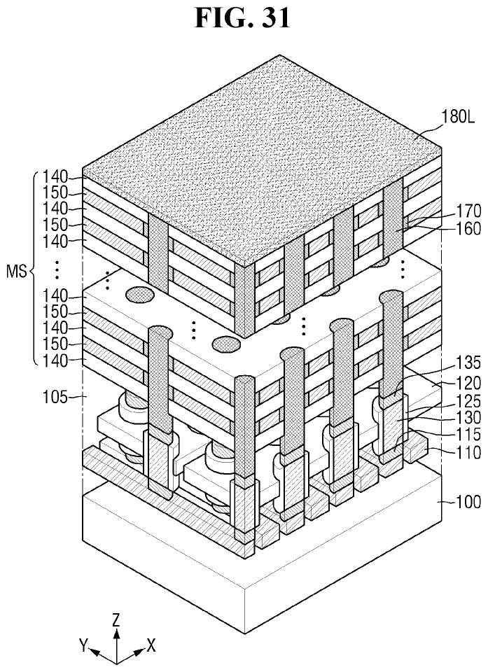

FIGS. 31 through 33 are perspective views illustrating intermediate steps of a method of fabricating a nonvolatile memory device according to some embodiments of the present disclosure. For convenience of description, redundant or repetitive portions that overlap with the content described earlier with reference to FIGS. 1 through 28 will be briefly mentioned or omitted. Specifically, FIG. 31 illustrates an intermediate step to be performed after that depicted in FIG. 27.

Referring to FIG. 31, a preliminary charge dissipation layer 180L is formed on a mold stack MS and conductive pillars 160.

The preliminary charge dissipation layer 180L may extend along the top surface of the mold stack MS and the top surfaces of the conductive pillars 160. The preliminary charge dissipation layer 180L may include an insulating material, for example, at least one of silicon oxide, silicon nitride, or silicon oxynitride, but the present disclosure is not limited thereto. In some embodiments, the preliminary charge dissipation layer 180L may include an oxide-based material. For example, the preliminary charge dissipation layer 180L may include a silicon oxide film.

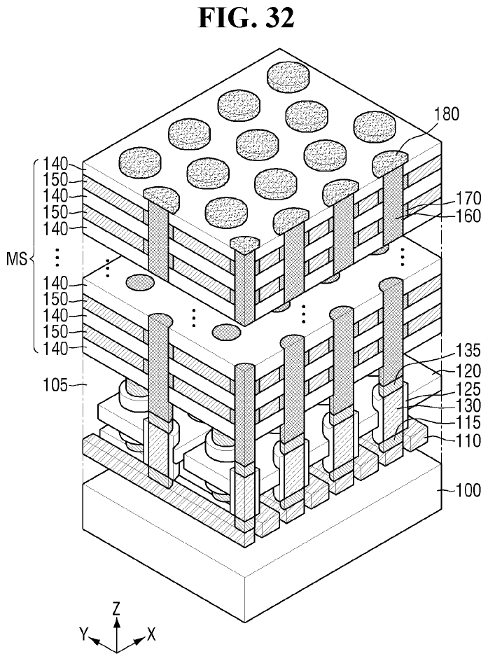

Referring to FIGS. 31 and 32, a plurality of charge dissipation layers 180 may be formed from the preliminary charge dissipation layer 180L.

For example, a patterning process may be performed on the preliminary charge dissipation layer 180L. As a result of the patterning process, a plurality of charge dissipation layers 180, which correspond to the conductive pillars 160, may be formed. As the conductive pillars 160 are spaced apart from one another on a plane (e.g., an XY plane) that is parallel to the top surface of a substrate 100, the charge dissipation layers 180, which correspond to the conductive pillars 160, may also be spaced apart from one another.

The width of the charge dissipation layers 180 may be greater than the width of the conductive pillars 160, but the present disclosure is not limited thereto. Alternatively, the width of the charge dissipation layers 180 may be the same as the width of the conductive pillars 160.

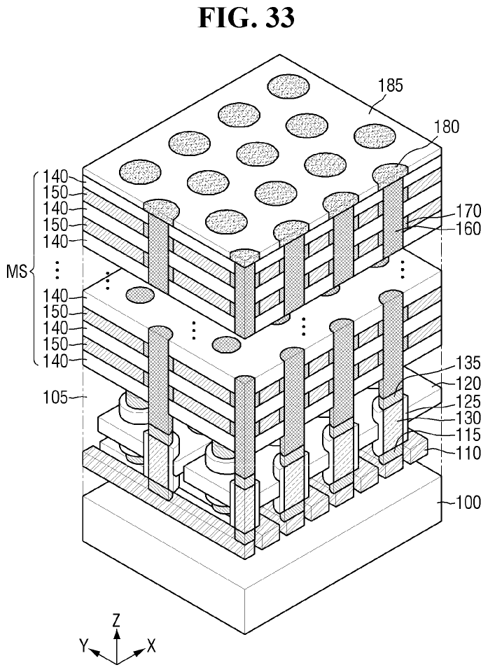

Referring to FIG. 33, a filling insulating film 185 is formed on the mold stack MS.

The filling insulating film 185 may separate the charge dissipation layers 180 from one another. For example, an insulating film, which is on (e.g., covers) the mold stack MS and the charge dissipation layers 180, may be formed. Thereafter, a planarization process may be performed on the insulating film. As a result of the planarization process, the top surfaces of the charge dissipation layers 180 may be exposed from the filling insulating film 185.

Thereafter, referring again to FIG. 9, a conductive layer 190 is formed on the charge dissipation layers 180 and the filling insulating film 185. In this manner, the nonvolatile memory device of FIGS. 9 and 10 may be fabricated.

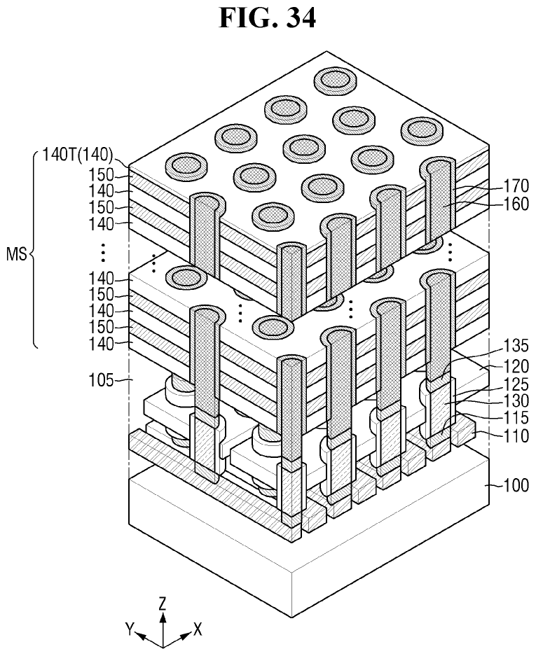

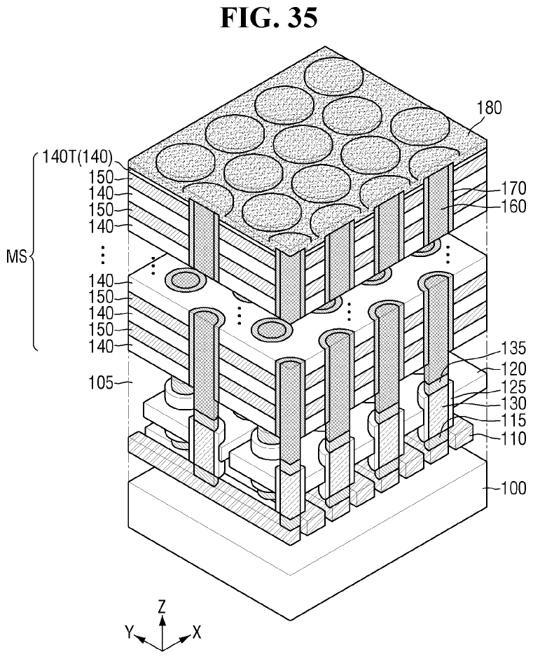

FIGS. 34 and 35 are perspective views illustrating intermediate steps of a method of fabricating a nonvolatile memory device according to some embodiments of the present disclosure. For convenience of description, redundant or repetitive portions that overlap with the content described earlier with reference to FIGS. 1 through 22 will be briefly mentioned or omitted. Specifically, FIG. 34 illustrates an intermediate step to be performed after that depicted in FIG. 21.

Referring to FIG. 34, a second etch-back process is performed on a mold stack MS.

As a result of the second etch-back process, conductive pillars 160 may protrude beyond the top surface of the mold stack MS (e.g., in the third direction Z). For example, the top surfaces of the conductive pillars 160 may be formed to be higher than the top surface of an uppermost mold insulating film 140T in the third direction Z (e.g., relative to the top surface of the substrate 100).

Referring to FIG. 35, a charge dissipation layer 180 is formed on the mold stack MS and the conductive pillars 160.

The charge dissipation layer 180 may be on (e.g., may cover) the mold stack MS and the conductive pillars 160. For example, the charge dissipation layer 180 may extend conformally along the top surface of the uppermost mold insulating film 140T and the top surfaces of the conductive pillars 160.

Thereafter, referring again to FIG. 11, a conductive layer 190 is formed on the charge dissipation layer 180. In this manner, the nonvolatile memory device of FIGS. 11 and 12 may be fabricated.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof.

While the present inventive concepts have been particularly shown and described with reference to example embodiments thereof, it will be understood by those of ordinary skill in the art that various changes in form and details may be made therein without departing from the scope of the present inventive concepts as defined by the following claims. It is therefore desired that the present example embodiments be considered in all respects as illustrative and not restrictive, reference being made to the appended claims rather than the foregoing description to indicate the scope of the invention.

What is claimed is:

1. A nonvolatile memory device comprising:
a substrate;
a plurality of gate electrodes stacked on the substrate;
a first conductive pillar that extends in a first direction perpendicular to a top surface of the substrate and intersects the plurality of gate electrodes;
a second conductive pillar that extends in the first direction and intersects the plurality of gate electrodes, the second conductive pillar being spaced apart from the first conductive pillar;
an information storage film between the first conductive pillar and each of the plurality of gate electrodes and between the second conductive pillar and each of the plurality of gate electrodes, the information storage film comprising chalcogenide;
a conductive layer spaced apart from the plurality of gate electrodes in the first direction;
a first charge dissipation layer between the first conductive pillar and the conductive layer; and
a second charge dissipation layer between the second conductive pillar and the conductive layer, the second charge dissipation layer being spaced apart from the first charge dissipation layer.

2. The nonvolatile memory device of claim 1, wherein the chalcogenide comprises selenium (Se), arsenic (As), and germanium (Ge).

3. The nonvolatile memory device of claim 1, wherein the first charge dissipation layer comprises an oxide of a material included in the first conductive pillar, and
wherein the second charge dissipation layer comprises an oxide of a material included in the second conductive pillar.

4. The nonvolatile memory device of claim 1, wherein each of the first charge dissipation layer and the second charge dissipation layer comprises an oxide-based material.

5. The nonvolatile memory device of claim 1, further comprising:
a first conductive line spaced apart from the plurality of gate electrodes in the first direction, the first conductive line extending in a second direction that intersects the first direction;
a second conductive line that extends in a third direction between the plurality of gate electrodes and the first conductive line, the third direction intersecting the first and second directions; and
a selection channel pattern that extends into the second conductive line in the first direction, the selection channel pattern configured to electrically connect the first conductive line to the first conductive pillar or electrically connect the second conductive line to the first conductive pillar.

6. The nonvolatile memory device of claim 1, further comprising:
a first barrier layer between the information storage film and each of the plurality of gate electrodes; and
a second barrier layer between the information storage film and the first conductive pillar.

7. The nonvolatile memory device of claim 6, wherein each of the first barrier layer and the second barrier layer comprises a carbon layer.

8. The nonvolatile memory device of claim 1, wherein the plurality of gate electrodes comprise a first wordline and a second wordline stacked on the substrate,
wherein the information storage film comprises a first sub-storage film between the first wordline and the first conductive pillar, and a second sub-storage film between the second wordline and the first conductive pillar, and
wherein the first sub-storage film and the second sub-storage film are spaced apart from each other in the first direction.

9. The nonvolatile memory device of claim 1, wherein the plurality of gate electrodes are between the substrate and the conductive layer.

10. The nonvolatile memory device of claim 1, wherein the conductive layer is between the substrate and the plurality of gate electrodes.

11. A nonvolatile memory device comprising:
a substrate;
a mold stack comprising mold insulating films and gate electrodes alternately stacked on the substrate;
a plurality of conductive pillars spaced apart from one another, each of the plurality of conductive pillars extending into the mold stack in a first direction perpendicular to a top surface of the substrate;
a plurality of information storage films between the mold stack and each of the plurality of conductive pillars, each of the plurality of information storage films comprising chalcogenide;
a conductive layer on the mold stack;
a plurality of charge dissipation layers between the conductive layer and each of the plurality of conductive pillars, the plurality of charge dissipation layers being spaced apart from one another;
a first conductive line that extends on the substrate in a second direction intersecting the first direction;
a second conductive line that extends in a third direction between the first conductive line and the mold stack, the third direction intersecting the first and second directions;
a selection channel pattern that extends into the second conductive line in the first direction, the selection channel pattern configured to electrically connect the first conductive line to one of the plurality of conductive pillars; and
a selection gate dielectric film between the second conductive line and the selection channel pattern.

12. The nonvolatile memory device of claim 11, wherein the chalcogenide comprises selenium (Se), arsenic (As), and germanium (Ge).

13. The nonvolatile memory device of claim 11, wherein each of the plurality of charge dissipation layers comprises an oxide of a material included in each of the plurality of conductive pillars.

14. The nonvolatile memory device of claim 11, wherein each of the plurality of charge dissipation layers comprises an oxide-based material.

15. The nonvolatile memory device of claim 11, wherein the conductive layer extends along a top surface of the mold stack and top surfaces of the plurality of charge dissipation layers.

16. The nonvolatile memory device of claim 15, wherein the first conductive line is between the substrate and the mold stack.

17. The nonvolatile memory device of claim 11, wherein the mold insulating films protrude beyond the gate electrodes toward the conductive pillars.

18. The nonvolatile memory device of claim 11, further comprising:
a first contact pattern that electrically connects the first conductive line to the selection channel pattern; and
a second contact pattern that electrically connects the selection channel pattern to one of the plurality of conductive pillars.

19. A nonvolatile memory device comprising:
a substrate;
a mold stack comprising mold insulating films and gate electrodes alternately stacked on the substrate;
a plurality of conductive pillars spaced apart from one another, each of the plurality of conductive pillars extending into the mold stack in a first direction perpendicular to a top surface of the substrate;
a plurality of information storage films between the mold stack and each of the plurality of conductive pillars, the information storage films comprising chalcogenide;
a charge dissipation layer that extends along a top surface of the mold stack and top surfaces of the plurality of conductive pillars; and
a conductive layer on a top surface of the charge dissipation layer,
wherein each of the plurality of conductive pillars protrudes beyond the top surface of the mold stack.

20. The nonvolatile memory device of claim 19, wherein the charge dissipation layer extends conformally along profiles of the top surface of the mold stack and the top surfaces of the plurality of conductive pillars.
